(19) United States
(12) Patent Application Publication
(10) Pub. No.: US 2025/0022816 A1
(43) Pub. Date: Jan. 16, 2025

(54) RADIO FREQUENCY MODULE AND MANUFACTURING METHOD OF RADIO FREQUENCY MODULE

(71) Applicant: Murata Manufacturing Co., Ltd., Nagaokakyo-shi, Kyoto (JP)

(72) Inventors: Takaya NEMOTO, Nagaokakyo-shi (JP); Hideki UEDA, Nagaokakyo-shi (JP); Michiharu YOKOYAMA, Nagaokakyo-shi (JP)

(73) Assignee: Murata Manufacturing Co., Ltd., Nagaokakyo-shi, Kyoto (JP)

(21) Appl. No.: 18/896,937

(22) Filed: Sep. 26, 2024

Related U.S. Application Data
(63) Continuation of application No. PCT/JP2023/008087, filed on Mar. 3, 2023.

(30) Foreign Application Priority Data
Mar. 31, 2022 (JP) 2022-057917

(51) Int. Cl. H01L 23/66; H01L 23/00; H01L 23/31; H01L 23/498; H01L 23/552; H01L 25/11

(52) U.S. Cl. CPC H01L 23/66; H01L 23/3107; H01L 23/49816; H01L 23/552; H01L 24/16; H01L 25/115; H01L 2224/16227; H01L 2924/14215

(57) ABSTRACT

A radio frequency module comprises a first component, a second component and a pedestal all supported by a first surface. The first component, the second component and pedestal all extend along a first axis perpendicular to the first surface. Along the first axis, the first component is longer than the second component and the pedestal is between the second component and the first surface. A first solder is between the first surface and the first component, a second solder is between the pedestal and the second component, and a third solder is between the first surface and the pedestal. Along a second axis which is parallel to the first surface, a first dimension of the first solder is greater than a second dimension of the second solder, and
a third dimension of the third solder is greater than the second dimension.

### CROSS-REFERENCE TO RELATED APPLICATIONS

The present application is a continuation application of PCT International Application No. PCT/JP2023/008087 filed on Mar. 3, 2023, designating the United States of America, which is based on and claims priority to Japanese patent application JP 2022-057917, filed Mar. 31, 2022. The entire disclosures of the above-identified applications, including the specifications, the drawings, and the claims are incorporated herein by reference in their entirety.

### BACKGROUND

With the thinning of a portable terminal or the like, further size reduction and height reduction of a radio frequency module mounted in the portable terminal are required. A radio frequency module in the related art is composed of an interposer substrate, a plurality of electronic circuit components mounted on the interposer substrate, and a resin member that seals the electronic circuit components.

A radio frequency module that does not include an interposer is known generally. Since the interposer is not provided, it is possible to achieve the height reduction.

### SUMMARY

An aspect of the present disclosure provides a radio frequency module comprising: a first component supported by a first surface, the first component extending along a first axis perpendicular to the first surface; a pedestal supported by the first surface, the pedestal extending along the first axis; and a second component supported by the pedestal, the second component extending along the first axis. Along the first axis, the first component is longer than the second component and the pedestal is between the second component and the first surface. A first solder is between the first surface and the first component, a second solder is between the pedestal and the second component, and a third solder is between the first surface and the pedestal. Along a second axis which is parallel to the first surface: a first dimension W1 of the first solder is greater than a second dimension W2 of the second solder, and a third dimension W3 of the third solder is greater than the second dimension W2.

Another aspect of the present disclosure provides a radio frequency module comprising a first component supported by a first surface, the first component extending along a first axis perpendicular to the first surface; a pedestal supported by the first surface, the pedestal extending along the first axis; a second component supported by the pedestal the second component extending along the first axis; and a plurality of first external terminals and a plurality of second external terminals that are supported by the first surface. The first component is connected to the first plurality of external terminals, and the second component is connected to the second plurality of external terminals via wirings extending through the pedestal. Along the first axis, the first component is longer than the second component and the pedestal is between the second component and the first surface. A first solder is between the first surface and the first component, a second solder is between the pedestal and the second component, and a third solder is between the first surface and the pedestal. Along a second axis which is parallel to the first surface: a first dimension W1 of the first solder is greater than a second dimension W2 of the second solder, and a third dimension W3 of the third solder is greater than the second dimension W2.

### Advantageous Effects of Disclosure

The first external terminal and the second external terminal can be used as external terminals for being mounted on another substrate or the like. A degree of variation in a size of the terminal may be smaller than in a case where the first external terminal and the second internal terminal are used as external connection terminals. As a result, it is possible to stably mount the radio frequency module on the substrate. In addition, with the configuration in which the temporary substrate is polished or ground, it is possible to achieve the height reduction in the radio frequency module 100.

### BRIEF DESCRIPTION OF DRAWINGS

FIG. 1 is a schematic cross-sectional view of a radio frequency module according to a first embodiment.

FIG. 2 is a bottom view of the radio frequency module according to the first embodiment.

FIG. 3 is a plan view illustrating an example of a positional relationship between a first component and a first external terminal and shapes thereof.

FIG. 4 is a cross-sectional view of an antenna module equipped with the radio frequency module according to the first embodiment.

FIG. 5 is an equivalent circuit diagram of a portion of the antenna module equipped with the radio frequency module according to the first embodiment.

FIG. 6 is a cross-sectional view of the radio frequency module according to the first embodiment in a middle stage of manufacturing.

FIG. 7 is a cross-sectional view of the radio frequency module according to the first embodiment in the middle stage of manufacturing.

FIG. 8 is a cross-sectional view of the radio frequency module according to the first embodiment in the middle stage of manufacturing.

FIG. 9 is a cross-sectional view of the radio frequency module according to the first embodiment in the middle stage of manufacturing.

FIGS. 10A and 10B are schematic cross-sectional views illustrating a procedure of applying solder onto a land disposed on a mounting surface of a mounting substrate.

FIG. 11 is a schematic cross-sectional view of the radio frequency module according to the first embodiment in a middle stage of another manufacturing method.

FIG. 12 is a schematic cross-sectional view of the radio frequency module according to the first embodiment in the middle stage of the other manufacturing method.

FIG. 13 is a schematic cross-sectional view of the radio frequency module according to the first embodiment in the middle stage of the other manufacturing method.

FIG. 14 is a schematic cross-sectional view of the radio frequency module according to the first embodiment in the middle stage of the other manufacturing method.

FIG. 15 is a schematic cross-sectional view of the radio frequency module according to the first embodiment in the middle stage of the other manufacturing method.

FIG. 16 is a cross-sectional view of a radio frequency module according to a modification example of the first embodiment.

FIG. 17 is a cross-sectional view of a radio frequency module according to another modification example of the first embodiment.

FIG. 18 is a cross-sectional view of a radio frequency module according to still another modification example of the first embodiment.

FIG. 19 is a cross-sectional view of a radio frequency module according to still another modification example of the first embodiment.

FIG. 20 is a cross-sectional view of the radio frequency module according to the second embodiment.

FIG. 21 is a cross-sectional view of a radio frequency module according to a third embodiment.

FIG. 22 is a diagram illustrating a positional relationship in plan view among a plurality of components included in the radio frequency module according to the third embodiment.

FIG. 23 is a cross-sectional view of a radio frequency module according to a fourth embodiment.

FIG. 24 is a diagram illustrating a positional relationship in plan view among a plurality of components included in the radio frequency module according to the fourth embodiment.

FIG. 25 is a cross-sectional view of a shield functional component included in the radio frequency module according to the fourth embodiment.

### DESCRIPTION OF EMBODIMENTS

Sizes of external terminals of the plurality of electronic circuit components constituting the radio frequency module are not the same as each other. For example, the size of the external terminal is different between a radio frequency integrated circuit (RFIC), a duplexer, a filter, a capacitor, an inductor, and the like.

In the radio frequency module disclosed in Patent Document 1, a plurality of components is supported by a support member, and external terminals of the plurality of components are exposed on one surface of the support member. That is, a plurality of external terminals having different sizes are exposed on one surface.

In a case where solder is placed on the external terminals having different sizes and a reflow treatment is performed, a height of a solder bump varies for each external terminal. Therefore, in a case where the radio frequency module is mounted on another substrate, connection failure tends to occur or an implementation state tends to be unstable. An object of the present disclosure is to provide a radio frequency module that is suitable for height reduction and can be stably mounted on a substrate.

### Solution to Problem

### First Embodiment

A radio frequency module and a manufacturing method thereof according to a first embodiment will be described with reference to FIGS. 1 to 10B.

FIG. 1 is a schematic cross-sectional view of a radio frequency module 100 according to the first embodiment. In the present specification, the term “schematic cross-sectional view” does not represent a cross section obtained by cutting the radio frequency module 100 on a specific plane, but represents a single diagram created by connecting cross sections at respective positions of a plurality of components included in the radio frequency module 100.

A plurality of first components 30, a second component 40, and a pedestal 50 are covered with and supported by a support member 70 made of a resin. For example, the support member 70 is in contact with surfaces of the first components 30, the second component 40, and the pedestal 50 to support these components. The support member 70 has a first surface 70A and a second surface 70B that face opposite directions and are disposed substantially parallel to each other. A direction in which the first surface 70A and the second surface 70B are separated from each other is defined as a height direction. A direction perpendicular to the first surface 70A can also be referred to as the height direction. Here, the term “perpendicular direction” does not mean a direction that is strictly perpendicular in a geometrical sense, and includes a substantially perpendicular direction.

A plurality of first external terminals 61, a plurality of second external terminals 62, and a plurality of long terminals 68 are exposed on the first surface 70A. The plurality of long terminals 68 are not essential, and the long terminal 68 need not be provided. Exposed surfaces of the plurality of first external terminals 61, the plurality of second external terminals 62, and the plurality of long terminals 68 are substantially flush with the first surface 70A. In other words, the plurality of first external terminals 61, the plurality of second external terminals 62, and the plurality of long terminals 68 are disposed at the same position in the height direction as the first surface 70A. Due to a variation in a manufacturing process, a slight step may occur between the exposed surfaces of the plurality of first external terminals 61, the plurality of second external terminals 62, and the plurality of long terminals 68, and a boundary with the first surface 70A.

Here, the disposition of the first external terminal 61 at the same position in the height direction as the first surface 70A means that the position in the height direction of one of two surfaces of the first external terminal 61 intersecting the height direction is the same as the position in the height direction of the first surface 70A. The same applies to a positional relationship between the second external terminal 62 and the long terminal 68, and the first surface 70A in the height direction. The configuration in which “the positions in the height direction are the same” includes a case where a deviation occurs in the position in the height direction due to a variation within an allowable range in the manufacturing process.

Each first component 30 has a plurality of first internal terminals 31 disposed on a surface facing the same direction as the first surface 70A (hereinafter, may be referred to as a lower surface 30A). The plurality of first internal terminals 31 are connected to the plurality of respective first external terminals 61 with solder members 81 interposed therebetween. A surface of the first component 30 facing a direction opposite to the lower surface 30A (hereinafter, may be referred to as a top surface 30B) is covered with the support member 70.

The pedestal 50 has a lower surface 50A facing the same direction as the first surface 70A, a top surface 50B facing a direction opposite to the lower surface 50A, a plurality of lower surface side internal terminals 51 disposed on the lower surface 50A, a plurality of top surface side internal terminals 52 disposed on the top surface 50B, and a plurality of wirings 53 connecting the lower surface side internal terminals 51 and the top surface side internal terminals 52 to each other. A printed circuit board is used, for example, as the pedestal 50. The plurality of lower surface side internal terminals 51 are connected to the plurality of respective second external terminals 62 with solder members 82 interposed therebetween.

The second component 40 includes a plurality of second internal terminals 41 disposed on a surface facing the same direction as the first surface 70A (hereinafter, may be referred to as a lower surface 40A). The plurality of second internal terminals 41 are connected to the plurality of respective top surface side internal terminals 52 with solder members 85 interposed therebetween, so that the second component 40 is disposed to be superimposed on the pedestal 50 in the height direction and is fixed to the pedestal 50. A surface of the second component 40 facing a direction opposite to the lower surface 40A (hereinafter, may be referred to as a top surface 40B) is covered with the support member 70.

A height-direction dimension of the first component 30 is denoted by h1, a height-direction dimension of the second component 40 is denoted by h2, and a height-direction dimension of the pedestal 50 is denoted by h3. The height-direction dimension h2 of the second component 40 is smaller than the height-direction dimension h1 of the first component 30 having the largest height-direction dimension h1. That is, among the first components 30 other than the first component 30 having the largest height-direction dimension h1, there may be the first component 30 having the height-direction dimension h1 smaller than the height-direction dimension h2 of the second component 40. The height-direction dimension h3 of the pedestal 50 is also smaller than the height-direction dimension h1 of the first component 30 having the largest height-direction dimension h1.

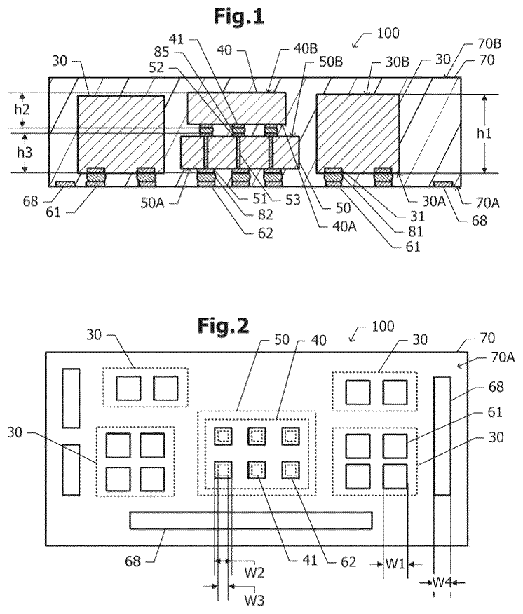

FIG. 2 is a bottom view of the radio frequency module 100 according to the first embodiment. The plurality of first components 30, the second component 40, and the pedestal 50 are supported by the support member 70. The plurality of first external terminals 61 connected to the respective first components 30 are exposed on the first surface 70A. The second external terminal 62 connected to the pedestal 50 is exposed on the first surface 70A. Further, the plurality of long terminals 68 are exposed on the first surface 70A.

When the first surface 70A is viewed in plan view (hereinafter, may be simply referred to as “in plan view”), the second component 40 is included in the pedestal 50. At least a portion of the second component 40 may be in a positional relationship of overlapping with at least a portion of the pedestal 50. The second component 40 has the plurality of second internal terminals 41. In plan view, the plurality of second internal terminals 41 overlap with the plurality of respective second external terminals 62.

In plan view, a minimum dimension of each of the plurality of first external terminals 61 is denoted by W1, a minimum dimension of each of the plurality of second external terminals 62 is denoted by W2, a minimum dimension of the second internal terminal 41 is denoted by W3, and a minimum dimension of the long terminal 68 is denoted by W4. The term “minimum dimension” is defined as, when a plane figure is interposed in various directions between two parallel lines in contact with the plane figure on both sides, a minimum distance between the two parallel lines. For example, in a case where the plane figure has a square shape, the minimum dimension thereof is equal to a length of one side, and in a case where the plane figure has a rectangular shape, the minimum dimension thereof is equal to a length of the short side. In a case where the plane figure has a circular shape, the minimum dimension thereof is equal to a length of a diameter, and in a case where the plane figure has an elliptical shape, the minimum dimension thereof is equal to a length of a minor axis.

In plan view, a maximum value of the minimum dimension W1 of each of the plurality of first external terminals 61 is larger than a maximum value of the minimum dimension W3 of each of the plurality of second internal terminals 41. Further, a maximum value of the minimum dimension W2 of each of the second external terminals 62 is larger than the maximum value of the minimum dimension W3 of each of the plurality of second internal terminals 41. The maximum value of the minimum dimension W2 of each of the second external terminals 62 is equal to or smaller than the maximum value of the minimum dimension W1 of each of the first external terminals 61. The maximum value of the minimum dimension W4 of the long terminal 68 is equal to or larger than the maximum value of the minimum dimension W2 of the second external terminal 62 and is equal to or smaller than the maximum value of the minimum dimension W1 of the first external terminal 61. That is, the following expression is established. Here, max means a maximum value of a parameter in parentheses.

$$max ( W 1 ) > max ( W 3 )$$

$$max ( W 2 ) > max ( W 3 )$$

$$max ( W 1 ) \geq max ( W 2 )$$

$$max ( W 2 ) \leq max ( W 4 ) \leq max ( W 1 )$$

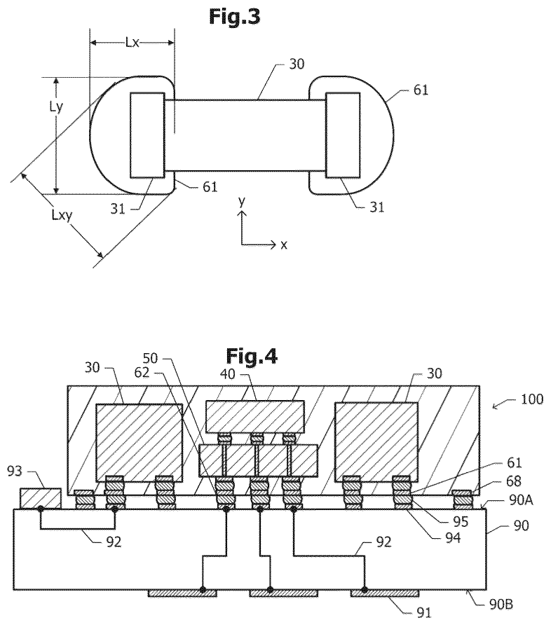

Next, the minimum dimension in a case where the shape of the first external terminal 61 in plan view is a shape other than the square shape, the circular shape, or the like will be described with reference to FIG. 3. FIG. 3 is a plan view illustrating an example of a positional relationship between the first component 30 and the first external terminal 61 and the shapes thereof. The first component 30 has two first internal terminals 31. The two first internal terminals 31 are connected to two respective first external terminals 61. A contour line of each of the two first external terminals 61 includes a linear portion and a substantially semicircular portion connecting both ends of the linear portion. The two first external terminals 61 are disposed with the linear portions facing each other.

An xy rectangular coordinate system in which a direction in which the two first external terminals 61 are separated from each other is an x direction is defined. An x-direction dimension of each of the first external terminals 61 is denoted by Lx, and a y-direction dimension thereof is denoted by Ly. In the example illustrated in FIG. 3, the x-direction dimension Lx is smaller than the y-direction dimension Ly. In addition, the diagonal-direction dimension Lxy is larger than the x-direction dimension Lx in any direction. In this case, the minimum dimension W1 of the first external terminal 61 is equal to the x-direction dimension Lx.

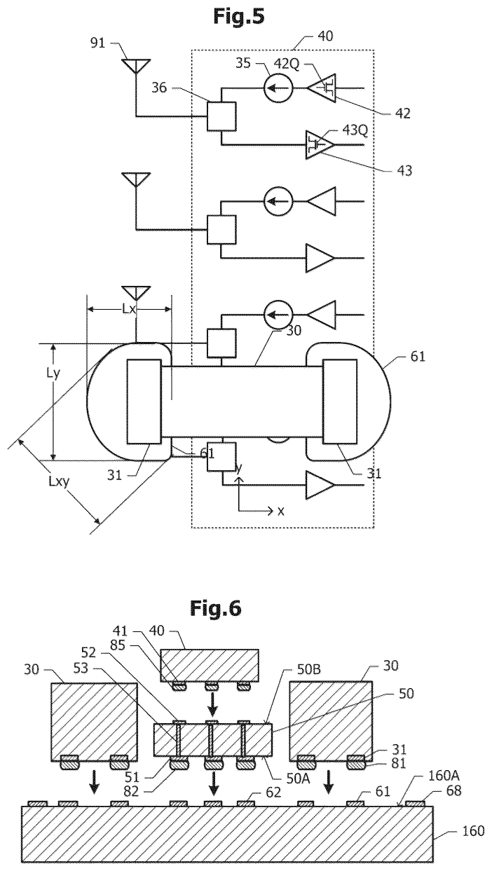

Next, an antenna module equipped with the radio frequency module according to the first embodiment will be described with reference to FIGS. 4 and 5.

FIG. 4 is a cross-sectional view of the antenna module equipped with the radio frequency module 100 according to the first embodiment. The radio frequency module 100 is mounted on an antenna substrate 90. The antenna substrate 90 has a plurality of lands 94 disposed on a mounting surface 90A on which the radio frequency module 100 is mounted. The plurality of first external terminals 61, the plurality of second external terminals 62, and the plurality of long terminals 68 of the radio frequency module 100 are connected to the plurality of respective lands 94 with solder members 95 interposed therebetween.

A plurality of antenna elements 91 are disposed on an antenna surface 90B of the antenna substrate 90 opposite to the mounting surface 90A. As the antenna element 91, for example, a patch antenna is used. In FIG. 4, the description of a ground plane constituting the patch antenna is omitted. The antenna element 91 may be disposed in an inner layer of the antenna substrate 90, or may have a configuration in which the antenna element 91 disposed on the antenna surface 90B is covered with a protective film made of a dielectric. In addition, an antenna disposed on the antenna substrate 90 may be an antenna other than the patch antenna.

The plurality of antenna elements 91 are connected to the plurality of respective lands 94 with the wirings 92 in the antenna substrate 90 interposed therebetween. That is, each of the plurality of antenna elements 91 are connected to the second component 40.

A radio frequency connector 93 is mounted on the mounting surface 90A of the antenna substrate 90. The radio frequency connector 93 is connected to one first external terminal 61 with the wiring 92 in the antenna substrate 90 interposed therebetween.

FIG. 5 is an equivalent circuit diagram of a portion of the antenna module equipped with the radio frequency module 100 according to the first embodiment. The second component 40 includes a plurality of power amplifiers 42, a plurality of low noise amplifiers 43, a plurality of isolators 35, and a plurality of duplexers 36. A radio frequency signal amplified by the power amplifier 42 is supplied to the antenna element 91 through the isolator 35 and the duplexer 36. The radio frequency signal received by the antenna element 91 is input to the low noise amplifier 43 through the duplexer 36.

Each of the power amplifier 42 and the low noise amplifier 43 includes an active element. For example, the power amplifier 42 includes a transistor 420, and the low noise amplifier 43 includes a transistor 43Q. Heat is generated mainly in the transistor 420 of the power amplifier 42 during the transmission of the radio frequency signal.

In FIG. 5, each of the plurality of antenna elements 91 is used as both a transmission antenna element and a reception antenna element, but the plurality of antenna elements 91 may be divided into the transmission antenna element and the reception antenna element. In this case, the duplexer 36 is not necessary. That is, the second component 40 may include a plurality of transmission systems and a plurality of reception systems.

In addition, FIG. 5 illustrates the antenna module having both the transmission and reception functions, but an antenna module having one of the transmission function or the reception function may be configured. In a case of configuring the antenna module having the transmission function, the low noise amplifier 43 is not necessary in the second component 40, and the power amplifier 42 need only be included in the second component 40. In a case of configuring the antenna module having the reception function, the power amplifier 42 is not necessary in the second component 40, and the low noise amplifier 43 need only be included in the second component 40.

Next, a manufacturing method of the radio frequency module according to the first embodiment will be described with reference to FIGS. 6 to 9. FIGS. 6 to 9 are cross-sectional views of the radio frequency module according to the first embodiment in the middle stage of manufacturing.

As illustrated in FIG. 6, the plurality of first external terminals 61, the plurality of second external terminals 62, and the plurality of long terminals 68 are formed on a first mounting surface 160A that is one surface of a temporary substrate 160. Further, the plurality of first components 30, the pedestal 50, and the second component 40 are prepared. By applying solder onto the first internal terminal 31 of the first component 30, the second internal terminal 41 of the second component 40, and the lower surface side internal terminal 51 of the pedestal 50 to perform a reflow treatment, the solder members 81, 82, and 85 are formed.

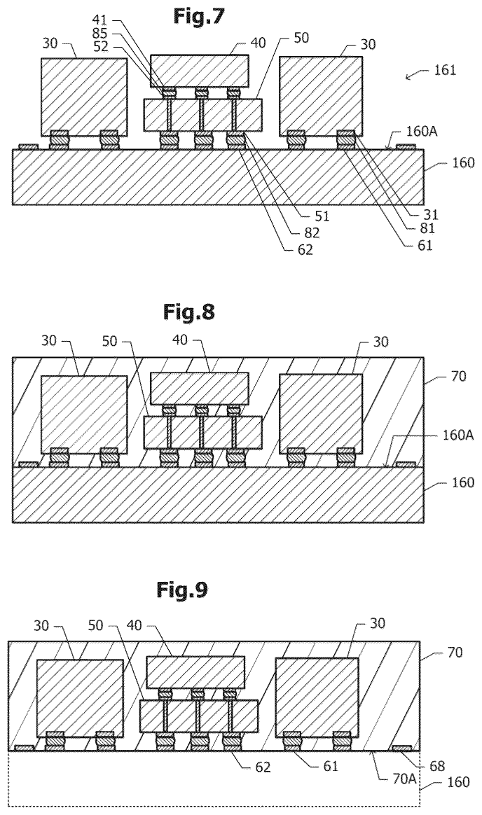

As illustrated in FIG. 7, the first internal terminal 31 of the first component 30 is connected to the first external terminal 61 with the solder member 81 interposed therebetween, so that the first component 30 is mounted on the temporary substrate 160. The lower surface side internal terminal 51 of the pedestal 50 is connected to the second external terminal 62 with the solder member 82 interposed therebetween, so that the pedestal 50 is mounted on the temporary substrate 160. The second internal terminal 41 of the second component 40 is connected to the top surface side internal terminal 52 with the solder member 85 interposed therebetween, so that the second component 40 is fixed to the pedestal 50.

Either the procedure of mounting the pedestal 50 on the temporary substrate 160 or the procedure of fixing the second component 40 to the pedestal 50 may be performed first. In the steps so far, an intermediate product 161 including the temporary substrate 160, the first component 30, the second component 40, and the pedestal 50 is produced.

As illustrated in FIG. 8, the support member 70 made of a resin is formed to cover the first mounting surface 160A of the temporary substrate 160, the first component 30, the second component 40, and the pedestal 50. For example, an insert molding technique can be used to form the support member 70.

As illustrated in FIG. 9, the temporary substrate 160 is polished or ground from a surface opposite to the first mounting surface 160A (FIG. 8) to expose the first external terminal 61, the second external terminal 62, and the long terminal 68. The first surface 70A of the support member 70 is exposed by polishing or grinding the temporary substrate 160.

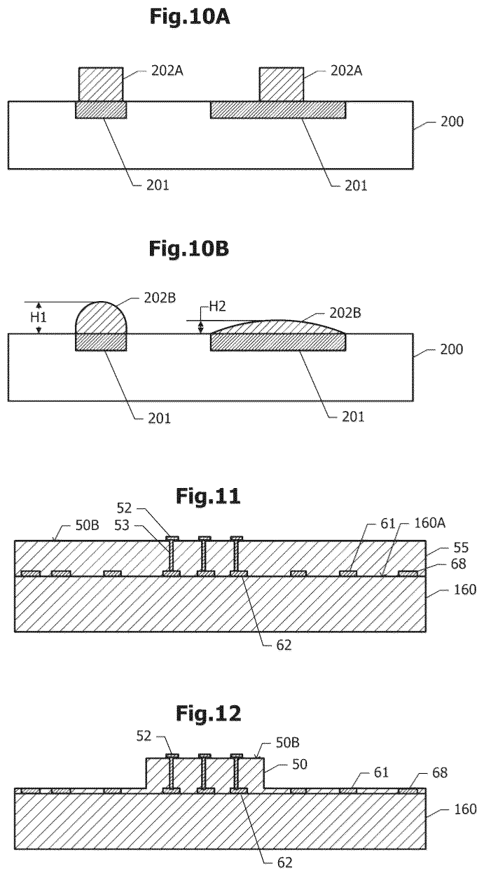

Next, an advantageous effect of the first embodiment will be described with reference to FIGS. 10A and 10B. FIGS. 10A and 10B are schematic cross-sectional views illustrating a procedure of applying solder 202A and solder 202B onto a land 201 disposed on a mounting surface of the mounting substrate 200.

As illustrated in FIG. 10A, a plurality of lands 201 having different sizes are disposed on the mounting surface of the mounting substrate 200. The solder 202A is applied onto each of the plurality of lands 201. For the application of the solder 202A, for example, screen printing is used. For example, the same volume of the solder 202A is applied onto each of the plurality of lands 201.

As illustrated in FIG. 10B, the applied solder 202A is subjected to the reflow treatment. The solder 202B after the reflow covers substantially an entire region of an upper surface of the land 201. A height H1 of the solder 202B on the land 201 having a relatively small area is higher than a height H2 of the solder 202B on the land 201 having a relatively large area. As described above, in a case where the size of the land 201 varies, the height of the solder 202B also varies, and a degree of variation in the height of the solder 202B is increased as a degree of variation in the area of the land 201 is increased. In particular, in a case where a degree of variation in a minimum dimension of the land 201 is increased in plan view, the degree of variation in the height of the solder 202B is also increased.

In general, a terminal of a component having a small height-direction dimension has a dimension smaller than a dimension of a terminal of a component having a large height-direction dimension. As illustrated in FIG. 2, the maximum value of the minimum dimension W2 of each of the second internal terminals 41 is smaller than the maximum value of the minimum dimension W1 of each of the first external terminals 61. In the structure in which the second internal terminal 41 is exposed on the first surface 70A, a degree of variation in the minimum dimension of each of a plurality of terminals including the first external terminals 61 and the second internal terminals 41 exposed on the first surface 70A is likely to be large.

In the first embodiment, the first external terminal 61 and the second external terminal 62 are exposed on the first surface 70A, and the maximum value of the minimum dimension W2 of each of the second external terminals 62 is larger than the maximum value of the minimum dimension W3 of each of the second internal terminals 41. Therefore, as compared with a configuration in which the first external terminal 61 and the second internal terminal 41 are exposed on the first surface 70A, the degree of variation in the minimum dimension of each of the plurality of terminals exposed on the first surface 70A is reduced. That is, the pedestal 50 has a function of increasing the dimension of the second external terminal 62 for connecting the second component 40 to an external substrate or the like to be larger than the dimension of the second internal terminal 41, to approach the dimension of the first external terminal 61.

In a case where the degree of variation in the minimum dimension of each of a plurality of terminals including the first external terminals 61 and the second external terminals 62 is reduced, the degree of variation in the height of the solder applied onto the first external terminal 61 and the second external terminal 62 is also reduced. As a result, it is possible to easily and stably mount the radio frequency module according to the first embodiment on another substrate, such as the antenna substrate 90 (FIG. 4).

In a case where the minimum dimension W2 of each of the second external terminals 62 is increased, and a difference from the minimum dimension W3 of each of the second internal terminals 41 is too large, a degree of discontinuity of a characteristic impedance of a feed line from the second internal terminal 41 to the antenna element 91 (FIG. 4) through the second external terminal 62 is increased. As a result, a transmission loss of the radio frequency signal is increased. In order to suppress the increase in the transmission loss of the radio frequency signal, it is preferable that the minimum dimension W2 of each of the second external terminals 62 is not made larger than necessary. For example, it is preferable that the maximum value of the minimum dimension W2 of each of the second external terminals 62 is equal to or smaller than the minimum dimension W1 of each of the first external terminals 61. In a case where the difference between the minimum dimension W2 of each of the second external terminals 62 and the minimum dimension W3 of each of the second internal terminals 41 is reduced, the degree of discontinuity of the characteristic impedance of the feed line from the second internal terminal 41 to the antenna element 91 (FIG. 4) through the second external terminal 62 is reduced. As a result, the transmission loss of the radio frequency signal is reduced.

In a case where a difference between the maximum value and a minimum value of the minimum dimension of each of the plurality of terminals including the first external terminals 61 and the second external terminals 62 is too large, it is difficult to stably mount the radio frequency module 100 on another substrate. In order to maintain the advantageous effect in that the radio frequency module 100 can be stably mounted on another substrate, it is preferable that the difference between the maximum value and the minimum value of the minimum dimension of each of the plurality of terminals including the first external terminals 61 and the second external terminals 62 is smaller than a difference between a maximum value and a minimum value of a minimum dimension of each of a plurality of terminals including the first external terminals 61 and the second internal terminals 41.

Further, in order to suppress the attenuation of the advantageous effect in that the radio frequency module 100 can be stably mounted on another substrate, it is preferable to adopt a configuration in which the maximum value of the minimum dimension W4 of each of the plurality of long terminals 68 is equal to or larger than the maximum value of the minimum dimension W2 of each of the second external terminals 62 and is equal to or smaller than the maximum value of the minimum dimension W1 of each of the plurality of first external terminals 61.

The height-direction dimension h2 of the second component 40 included in the radio frequency module 100 according to the first embodiment is smaller than the height-direction dimension h1 of the first component 30. Since the second component 40 having a relatively small height-direction dimension is disposed to be superimposed on the pedestal 50, the top surface 40B of the second component 40 is close to the second surface 70B of the support member 70. Therefore, a thermal resistance of a heat transfer path from the second component 40 to the second surface 70B of the support member 70 is reduced. As a result, the heat radiation from the second component 40 can be enhanced. In particular, in a case where the second component 40 includes the active element such as the transistor 420 (see FIG. 5) and is a main heat source of the radio frequency module 100, it is effective to enhance the heat radiation from the second component 40.

Further, in the first embodiment, the first component 30 is connected to the first external terminal 61 without the interposer or the like interposed therebetween. Therefore, it is possible to achieve the height reduction of the radio frequency module 100 as compared with a configuration including the interposer or the like. In a case where the height-direction dimension h3 of the pedestal 50 is too large, the effect of the height reduction is reduced. In order to maintain the advantageous effect in that the height reduction is achieved, it is preferable that the height-direction dimension h3 of the pedestal 50 is equal to or smaller than the height-direction dimension h1 of the first component 30 having the largest height-direction dimension h1. Further, it is preferable that a sum of the height-direction dimension h3 of the pedestal 50 and the height-direction dimension h2 of the second component 40 is 1.5 times or less the height-direction dimension h1 of the first component 30 having the largest height-direction dimension h1.

Next, another manufacturing method of the radio frequency module 100 according to the first embodiment will be described with reference to FIGS. 11 to 15. FIGS. 11 to 15 are schematic cross-sectional views of the radio frequency module according to the first embodiment in the middle stage of manufacturing.

As illustrated in FIG. 11, the plurality of first external terminals 61, the plurality of second external terminals 62, and the plurality of long terminals 68 are formed on the first mounting surface 160A that is one surface of the temporary substrate 160. Thereafter, the multilayer wiring structure 55 is formed on the first mounting surface 160A. In the step of forming the multilayer wiring structure 55, the plurality of wirings 53 consisting of via conductors and the like are formed. The plurality of top surface side internal terminals 52 are formed on the top surface 50B that is the uppermost surface of the multilayer wiring structure 55. The wiring 53 connects the second external terminal 62 and the top surface side internal terminal 52 to each other.

As illustrated in FIG. 12, a portion of the multilayer wiring structure 55 (FIG. 11) is removed until the first external terminal 61 and the long terminal 68 are exposed. Polishing or grinding is used to remove a portion of the multilayer wiring structure 55. In this case, the pedestal 50 consisting of a part of the multilayer wiring structure 55 is left in a region in which the second external terminal 62 and the top surface side internal terminal 52 are disposed.

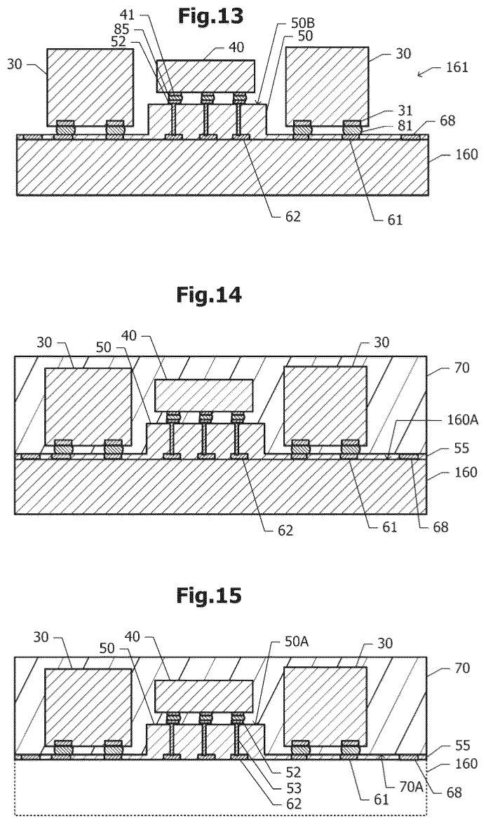

As illustrated in FIG. 13, the second component 40 is fixed to the top surface 50B of the pedestal 50 by connecting the second internal terminal 41 of the second component 40 to the top surface side internal terminal 52 with the solder member 85 interposed therebetween. The first component 30 is mounted on the temporary substrate 160 by connecting the first internal terminal 31 of the first component 30 to the first external terminal 61 with the solder member 81 interposed therebetween. In the steps so far, the intermediate product 161 including the temporary substrate 160, the first component 30, the second component 40, and the pedestal 50 is produced.

As illustrated in FIG. 14, the support member 70 made of a resin is formed to cover the first mounting surface 160A of the temporary substrate 160, the first external terminal 61, the long terminal 68, the pedestal 50, the first component 30, and the second component 40. For example, an insert molding technique can be used to form the support member 70. A thin layer of the multilayer wiring structure 55 is left on the first mounting surface 160A. The support member 70 covers the first mounting surface 160A with the thin layer interposed therebetween.

As illustrated in FIG. 15, the temporary substrate 160 is polished or ground from a surface opposite to the first mounting surface 160A until the first external terminal 61, the second external terminal 62, and the long terminal 68 are exposed. The first surface 70A of the support member 70 is covered with a thin insulating layer that is a portion of the multilayer wiring structure 55. The surfaces of the first external terminal 61 and the long terminal 68 facing the support member 70 side is in contact with the first surface 70A of the support member 70. The first external terminal 61 and the long terminal 68 protrude from the first surface 70A by the thicknesses of the first external terminal 61 and the long terminal 68. The second external terminal 62 is disposed at the same position as the first external terminal 61 and the long terminal 68 in the height direction.

The radio frequency module 100 manufactured by the present manufacturing method according to the embodiment does not include the lower surface side internal terminal 51 that is disposed on the pedestal 50 of the radio frequency module 100 illustrated in FIG. 1 and the solder member 82 that connects the lower surface side internal terminal 51 and the second external terminal 62. The wiring 53 connected to the top surface side internal terminal 52 is directly connected to the second external terminal 62.

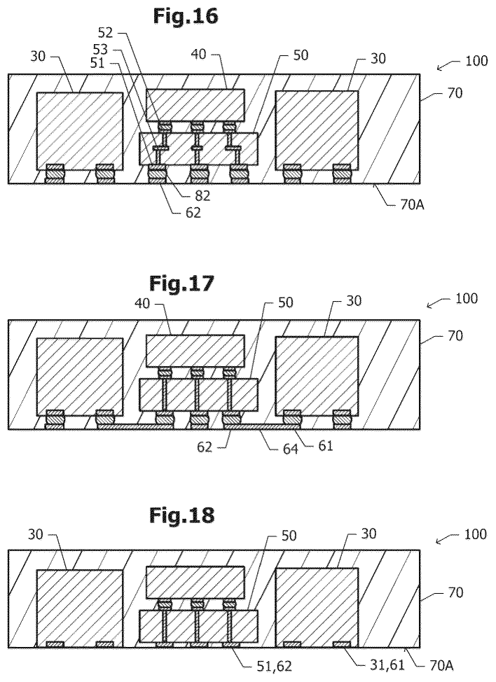

Next, a radio frequency module according to a modification example of the first embodiment will be described with reference to FIG. 16. FIG. 16 is a cross-sectional view of the radio frequency module 100 according to the modification example of the first embodiment. In the first embodiment (FIGS. 1 and 2), the lower surface side internal terminal 51 and the top surface side internal terminal 52 of the pedestal 50, which are connected to each other, are disposed at the same position in plan view. On the other hand, in the present modification example, at least a portion of the lower surface side internal terminal 51 and at least a portion of the top surface side internal terminal 52 of the pedestal 50, which are connected to each other, are disposed at different positions in plan view. For example, the disposition is adopted in which the minimum distance between the lower surface side internal terminals 51 is larger than the minimum distance between the top surface side internal terminals 52. In the present modification example, the pedestal 50 has a function as a rewiring layer of a fan-out package. In the present modification example, the long terminal 68 provided in the radio frequency module 100 (FIGS. 1 and 2) according to the first embodiment is not provided.

Next, a radio frequency module according to another modification example of the first embodiment will be described with reference to FIG. 17. FIG. 17 is a cross-sectional view of the radio frequency module 100 according to another modification example of the first embodiment. In the first embodiment (FIGS. 1 and 2), the plurality of first external terminals 61 and the plurality of second external terminals 62 are each composed of an isolated metal pattern. On the other hand, in the present modification example, at least one of the first external terminals 61 and at least one of the second external terminals 62 are connected to each other by a wiring 64 exposed on the first surface 70A. The wiring 64 can be formed on the first mounting surface 160A of the temporary substrate 160 at the same time as the first external terminal 61 and the like, for example, in the step illustrated in FIG. 6.

In the present modification example, the first component 30 and the second component 40 included in the radio frequency module 100 can be connected to each other in the radio frequency module 100. Therefore, the number of wirings in the mounting substrate on which the radio frequency module 100 is mounted can be reduced.

Next, a radio frequency module according to still another modification example of the first embodiment will be described with reference to FIG. 18. FIG. 18 is a cross-sectional view of the radio frequency module 100 according to still another modification example of the first embodiment.

In the first embodiment (FIG. 1), the first internal terminal 31 of the first component 30 and the first external terminal 61 exposed on the first surface 70A of the support member 70 are connected to each other with the solder member 81 interposed therebetween. On the other hand, in the present modification example, the first internal terminal 31 of the first component 30 is exposed on the first surface 70A, and the first internal terminal 31 is used as the first external terminal 61 for connection to the mounting substrate or the like. Similarly, the lower surface side internal terminal 51 of the pedestal 50 is exposed on the first surface 70A, and the lower surface side internal terminal 51 is used as the second external terminal 62.

The structure of the radio frequency module 100 according to the present modification example is produced by, for example, exposing, in the step of polishing or grinding the temporary substrate 160 illustrated in FIG. 9, the first external terminal 61, the second external terminal 62, and the long terminal 68, and then continuing the polishing or grinding until the first internal terminal 31 and the lower surface side internal terminal 51 are exposed.

In the present modification example, further height reduction of the radio frequency module 100 can be achieved. In the step illustrated in FIG. 9, the solder members 81 and 82 may be polished or ground to a middle portion, and the solder members 81 and 82 may be exposed on the first surface 70A. In this configuration, the solder member 81 and the solder member 82 are used as the first external terminal 61 and the second external terminal 62, respectively.

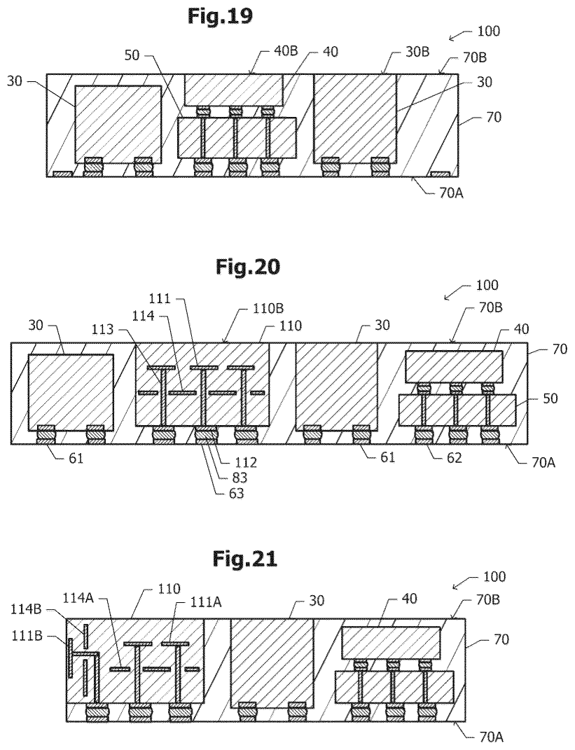

Next, a radio frequency module according to still another modification example of the first embodiment will be described with reference to FIG. 19. FIG. 19 is a cross-sectional view of the radio frequency module 100 according to still another modification example of the first embodiment.

In the first embodiment (FIG. 1), the top surface 30B of the first component 30 and the top surface 40B of the second component 40 are covered with the support member 70. On the other hand, in the present modification example, the top surface 30B of at least one first component 30 and the top surface 40B of the second component 40 are substantially flush with the second surface 70B of the support member 70 and are exposed from the support member 70. Such a structure can be produced by polishing or grinding the support member 70 from the second surface 70B after the step of polishing or grinding the temporary substrate 160 illustrated in FIG. 9.

By exposing the top surface 40B of the second component 40 from the support member 70, the heat radiation from the second component 40 can be further enhanced. In order to adopt this structure, the height-direction dimension of the pedestal 50 may be set such that the height from the first surface 70A to the top surface 40B of the second component 40 and the height to the exposed top surface 30B of the first component 30 are equal to each other.

### Second Embodiment

Next, a radio frequency module according to a second embodiment will be described with reference to FIG. 20. Hereinafter, the description of the configuration common to the radio frequency module 100 according to the first embodiment, which is described with reference to FIGS. 1 to 9, will be omitted.

FIG. 20 is a cross-sectional view of the radio frequency module 100 according to the second embodiment. In the second embodiment, an antenna component 110 is supported by the support member 70 in addition to the first component 30, the second component 40, and the pedestal 50. The antenna component 110 includes a plurality of radiating elements 111, a feed line 113 disposed for each radiating element 111, and a ground plane 114 inside. The ground plane 114 is disposed parallel to the first surface 70A, and the plurality of radiating elements 111 are disposed at positions farther from the ground plane 114 when viewed from the first surface 70A. The patch antenna is configured by each of the radiating elements 111 and the ground plane 114.

The antenna component 110 further includes a plurality of antenna terminals 112 disposed on a surface facing the same direction as the direction in which the first surface 70A faces. The plurality of antenna terminals 112 are connected to the plurality of respective radiating elements 111 via the feed lines 113 interposed therebetween. A plurality of third external terminals 63 are exposed on the first surface 70A in addition to the first external terminal 61 and the second external terminal 62. That is, the third external terminal 63 is disposed at the same position in the height direction as the first external terminal 61 and the second external terminal 62.

The plurality of antenna terminals 112 are connected to the plurality of respective third external terminals 63 with the solder members 83 interposed therebetween. A surface of the antenna component 110 facing a direction opposite to the direction in which the first surface 70A faces (hereinafter, may be referred to as a top surface 110B) is flush with the second surface 70B of the support member 70 and is exposed from the support member 70.

The second component 40 is, for example, a radio frequency integrated circuit (RFIC), and the second component 40 is connected to the radiating element 111 with the second external terminal 62, the wiring on the mounting substrate, the third external terminal 63, the solder member 83, the antenna terminal 112, and the feed line 113 interposed therebetween. As illustrated in FIG. 17, the second external terminal 62 and the third external terminal 63 may be connected to each other with the wiring exposed on the first surface 70A interposed therebetween, as in the modification example of the first embodiment.

The radio frequency signal is supplied from the second component 40 to each of the plurality of radiating elements 111, and a radio wave is emitted from each of the radiating elements 111. A boresight of the radiating element 111 faces the direction opposite to the direction in which the first surface 70A faces. That is, the boresight of the radiating element 111 faces a direction opposite to a direction of a boresight of the antenna element 91 of the antenna module illustrated in FIG. 4. The boresight is also called a main radiation direction.

Next, an advantageous effect of the second embodiment will be described.

In the second embodiment, as in the first embodiment, the radio frequency module 100 can be stably mounted on the mounting substrate, and the height reduction of the radio frequency module 100 can be achieved. Further, in the second embodiment, the radio waves can be radiated in a direction opposite to the direction in which the first surface 70A of the support member 70 faces. That is, the radio waves can be radiated in a direction in which the component mounting surface of the mounting substrate on which the radio frequency module 100 is mounted faces.

Next, a modification example of the second embodiment will be described. The radio frequency module 100 according to the second embodiment may be mounted on the antenna substrate 90 illustrated in FIG. 4. By adopting this configuration, it is possible to radiate the radio waves on both sides of the first surface 70A.

### Third Embodiment

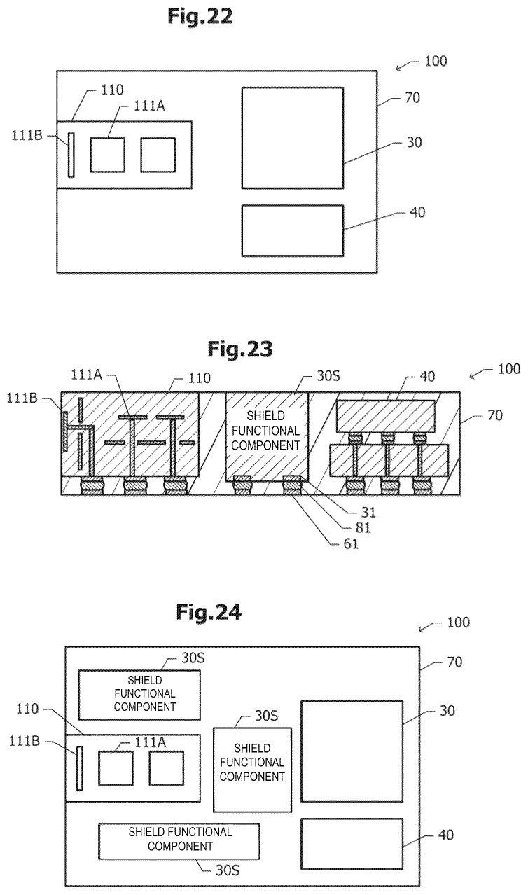

Next, a radio frequency module according to a third embodiment will be described with reference to FIGS. 21 and 22. Hereinafter, the description of the configuration common to the radio frequency module 100 according to the second embodiment, which is described with reference to FIG. 20, will be omitted.

FIG. 21 is a cross-sectional view of the radio frequency module 100 according to the third embodiment, and FIG. 22 is a diagram illustrating a positional relationship in plan view among the plurality of components included in the radio frequency module 100. In the second embodiment (FIG. 20), the directions of the boresights of the plurality of radiating elements 111 in the antenna component 110 are directions opposite to the direction in which the first surface 70A faces. On the other hand, in the third embodiment, the antenna component 110 includes two types of radiating elements 111A and 111B having different directions of the boresight. The boresight of the radiating element 111A of one type faces the direction opposite to the direction in which the first surface 70A faces, and the boresight of the radiating element 111B of the other type faces a direction parallel to the first surface 70A. The direction of the boresight of the radiating element 111B does not always have to be parallel to the first surface 70A, and may be inclined with respect to a plane including the first surface 70A. For example, the direction of the boresight may be inclined in a direction in which an inclination angle with respect to the plane including the first surface 70A is 45° or less. Hereinafter, the radiating element 111B may be referred to as a “lateral radiating element”. A ground plane 114A is disposed with respect to the radiating element 111A, and a ground plane 114B is disposed with respect to the radiating element 111B.

For example, each of the radiating element 111B and the ground plane 114B is configured of a metal pattern perpendicular to the first surface 70A. The radiating element 111B and the ground plane 114B constitute the patch antenna. The antenna component 110 having such a structure can be produced by using, for example, a 3D printer.

Next, an advantageous effect of the third embodiment will be described. In the third embodiment, as in the second embodiment, the radio frequency module 100 can be stably mounted on the mounting substrate, and the height reduction of the radio frequency module 100 can be achieved. Further, in the third embodiment, the radio waves can be radiated in the direction opposite to the direction in which the first surface 70A faces and the direction parallel to the first surface 70A.

Next, a radio frequency module according to a modification example of the third embodiment will be described.

The radio frequency module 100 according to the third embodiment includes one lateral radiating element 111B, but a plurality of lateral radiating elements 111B may be arranged in a direction parallel to the first surface 70A to constitute an antenna array. In addition, the plurality of lateral radiating elements 111B may be disposed, and the directions of the boresights of the plurality of respective radiating elements 111B may be directed in a plurality of directions parallel to the first surface 70A.

### Fourth Embodiment

Next, a radio frequency module according to a fourth embodiment will be described with reference to FIGS. 23 to 25. Hereinafter, the description of the configuration common to the radio frequency module according to the third embodiment, which is described with reference to FIGS. 21 and 22, will be omitted.

FIG. 23 is a cross-sectional view of the radio frequency module 100 according to the fourth embodiment, and FIG. 24 is a diagram illustrating a positional relationship in plan view among the plurality of components included in the radio frequency module 100. In the fourth embodiment, a shield functional component 30S is used for at least one of the plurality of first components 30. The shield functional component 30S has an electromagnetic shield function. At least one shield functional component 30S is disposed adjacent to the antenna component 110 in plan view. Here, the phrase “disposed adjacent to each other” means that the antenna component 110 and the shield functional component 30S are disposed close to each other such that other components are not disposed therebetween in plan view.

For example, in plan view, at least one shield functional component 30S is disposed between the antenna component 110 and the second component 40. The second component 40 is not disposed between the antenna component 110 and the shield functional component 30S. As illustrated in FIG. 24, in plan view, three shield functional components 30S are disposed to surround the antenna component 110 from three directions other than the direction of the boresight of the lateral radiating element 111B.

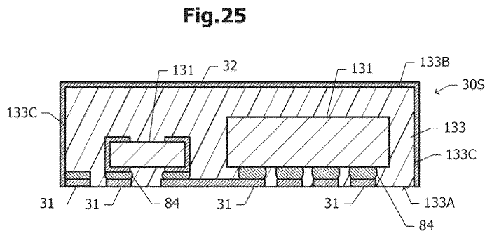

FIG. 25 is a cross-sectional view illustrating an example of the shield functional component 30S. The shield functional component 30S includes a plurality of sub-components 131. The plurality of sub-components 131 are covered with and supported by an internal support member 133. The internal support member 133 has a second surface 133A, and the plurality of first internal terminals 31 are exposed on the second surface 133A. The plurality of first internal terminals 31 are connected to the plurality of sub-components 131 with the solder members 84 interposed therebetween. As illustrated in FIG. 23, the plurality of first internal terminals 31 are connected to the plurality of first external terminals 61 with the solder members 81 interposed therebetween.

A top surface 133B of the internal support member 133, which faces a direction opposite to a direction in which the second surface 133A faces, and a side surface 133C connecting the second surface 133A and the top surface 133B to each other are covered with a metal film 32. The metal film 32 is covered with the support member 70 (FIG. 23). That is, the shield functional component 30S includes the metal film 32 disposed at an interface with the support member 70. As illustrated in FIG. 23, the metal film 32 that covers the top surface 133B of the internal support member 133 is exposed from the support member 70. A configuration may be adopted in which the metal film 32 that covers the top surface 133B of the internal support member 133 is covered with the support member 70.

At least one of the first internal terminals 31 is exposed on the side surface 133C of the internal support member 133 and is connected to the metal film 32. The metal film 32 is connected to the first external terminal 61 (see FIG. 23) with the first internal terminal 31 and the solder member 81 interposed therebetween. The first external terminal 61 connected to the metal film 32 is connected to a ground conductor of the mounting substrate.

As the shield functional component 30S, in addition to the component having the structure illustrated in FIG. 25, another component having a function of electromagnetically shielding the antenna component 110 may be used. As the shield functional component 30S, for example, a system-in-package (SiP) module in which a metal film is provided on a surface, a single component such as a shielded inductor, a composite component having a structure in which a metal member for heat radiation is in contact with a top surface of an electronic component, or the like may be used. In addition, as the shield functional component 30S, in addition to an electrical functional component, a component specialized in the electromagnetic shield function, for example, a metal member having various shapes, such as a metal block, may be used. The shield functional component 30S may include a metal portion disposed at the interface with the support member 70. This metal portion functions as an electromagnetic shield structure.

Next, an advantageous effect of the fourth embodiment will be described.

In the fourth embodiment, as in the third embodiment, the radio frequency module 100 can be stably mounted on the mounting substrate, and the height reduction of the radio frequency module 100 can be achieved. Further, the metal film 32 of the shield functional component 30S functions as an electromagnetic shield film. That is, the shield functional component 30S functions as a reflector that reflects the radio waves radiated from the antenna component 110. Therefore, it is possible to improve the radiation characteristics of the radiating elements 111A and 111B of the antenna component 110 in the boresight direction. Further, the isolation between the antenna component 110 and other components in the radio frequency module 100 can be enhanced.

Next, a radio frequency module according to a modification example of the fourth embodiment will be described.

In the fourth embodiment (FIG. 25), the entire region of the top surface 133B and the side surface 133C of the internal support member 133 is covered with the metal film 32, but a configuration may be adopted in which only a partial region thereof is covered with the metal film 32. In addition, the metal film 32 may have a shape with various patterns, for example, a mesh shape or a stripe shape.

Each of the above-described embodiments is merely an example, and it is needless to say that the configurations illustrated in different embodiments can be partially replaced or combined with each other. The same actions and effects of the same configurations in a plurality of embodiments are not sequentially referred to for each embodiment. Further, the present disclosure is not limited to the above-described embodiments. For example, it is obvious to a person skilled in the art that various modifications, improvements, combinations, and the like can be made.

### REFERENCE SIGNS LIST

30 first component
30A lower surface of first component
30B top surface of first component
30S shield functional component
31 first internal terminal
32 metal film
35 isolator
36 duplexer
40 second component
40A lower surface of second component
40B top surface of second component
41 second internal terminal
42 power amplifier
420 transistor
43 low noise amplifier
430 transistor
50 pedestal
50A lower surface of pedestal
50B top surface of pedestal
51 lower surface side internal terminal
52 top surface side internal terminal
53 wiring
55 multilayer wiring structure
61 first external terminal
62 second external terminal
63 third external terminal
64 wiring
68 long terminal
70 support member
70A first surface of support member
70B second surface of the support member
81, 82, 83, 84, 85 solder member
90 antenna substrate
90A mounting surface
90B antenna surface
91 antenna element
92 wiring
93 radio frequency connector
94 land
95 solder member
100 radio frequency module
110 antenna component
110B top surface of antenna component
111, 111A, 111B radiating element
112 antenna terminal
113 feed line
114, 114A, 114B ground plane
131 sub-component
133 internal support member
133A second surface of internal support member
133B top surface of internal support member
133C side surface of internal support member
160 temporary substrate
160A first mounting surface
161 intermediate product
200 mounting substrate
201 land
202A applied solder
202B solder after reflow treatment

1. A radio frequency module, comprising:
a first component supported by a first surface, the first component extending along a first axis perpendicular to the first surface;
a pedestal supported by the first surface, the pedestal extending along the first axis; and
a second component supported by the pedestal, the second component extending along the first axis, wherein
along the first axis, the first component is longer than the second component and the pedestal is between the second component and the first surface,
a first solder is between the first surface and the first component,
a second solder is between the pedestal and the second component,
a third solder is between the first surface and the pedestal, and
along a second axis which is parallel to the first surface:
a first dimension W1 of the first solder is greater than a second dimension W2 of the second solder, and
a third dimension W3 of the third solder is greater than the second dimension W2.

2. The radio frequency module according to claim 1, further comprising:
a first terminal between the pedestal and the first surface; and
a second terminal between the second component and the pedestal.

3. The radio frequency module according to claim 1, wherein the first dimension W1 is greater than or equal to the third dimension W3.

4. The radio frequency module according to claim 1, wherein the second component is an active element which generates heat.

5. The radio frequency module according to claim 1, wherein in a plan view, the second component is covered with a resin and the first component is exposed.

6. The radio frequency module according to claim 2, wherein in a plan view, the second terminal is not aligned with the first terminal.

7. The radio frequency module according to claim 1, further comprising an antenna.

8. The radio frequency module according to claim 7, further comprising a plurality of antennas including the antenna, wherein
a first antenna of the plurality of antennas faces a first direction along the first axis, and
a second antenna of the plurality of antennas faces a second direction different from the first direction.

9. The radio frequency module according to claim 7, further comprising a shield component supported by the first surface, wherein
the shield component is between the antenna and the pedestal and the second component, and
the shield component shields the pedestal and the second component from radiation emitted by the antenna.

10. The radio frequency module according to claim 1, further comprising a support member including the first surface and a second surface facing a direction opposite to a direction in which the first surface faces along the first axis.

11. The radio frequency module according to claim 10, further comprising a plurality of first components including the first component, wherein
at least one of the first component is exposed on the second surface.

12. The radio frequency module according to claim 1, wherein the first component is metal molded.

13. The radio frequency module according to claim 8,
wherein the antenna includes a plurality of radiating elements, a boresight of a part of the plurality of radiating elements faces a direction opposite to a direction in which the first surface faces, and a boresight of at least another part of the plurality of radiating elements faces a direction parallel to the first surface.

14. The radio frequency module according to claim 7, further comprising a plurality of first components including the first component,
wherein in a plan view, at least one of the first components is adjacent to the antenna, and
the at least one of the first components disposed adjacent to the antenna includes a metal portion disposed in at least a partial region of an interface with the first surface.

15. The radio frequency module according to claim 7, further comprising a system-in-package (SiP) module adjacent to the antenna component, wherein
the SiP includes a metal portion disposed in at least a partial region.

16. The radio frequency module according to claim 15, wherein the metal portion has a shape with patterns.

17. A radio frequency module, comprising:
a first component supported by a first surface, the first component extending along a first axis perpendicular to the first surface;
a pedestal supported by the first surface, the pedestal extending along the first axis;
a second component supported by the pedestal the second component extending along the first axis; and
a plurality of first external terminals and a plurality of second external terminals that are supported by the first surface, wherein
the first component is connected to the first plurality of external terminals,
the second component is connected to the second plurality of external terminals via wirings extending through the pedestal,
along the first axis, the first component is longer than the second component and the pedestal is between the second component and the first surface,
a first solder is between the first surface and the first component,
a second solder is between the pedestal and the second component,
a third solder is between the first surface and the pedestal, and
along a second axis which is parallel to the first surface:
a first dimension W1 of the first solder is greater than a second dimension W2 of the second solder, and
a third dimension W3 of the third solder is greater than the second dimension W2.

18. The radio frequency module according to claim 17, wherein the first dimension W1 is greater than or equal to the third dimension W3.

19. The radio frequency module according to claim 17, wherein in a plan view, the second component is covered with a resin and the first component is exposed.

20. The radio frequency module according to claim 17, further comprising:
an antenna supported by the first surface; and
a third external terminal supported by the first surface, wherein
the antenna includes a radiating element connected to the third external terminal.
